(19) United States
(12) Patent Application Publication
(10) Pub. No.: US 2020/0328364 A1
(43) Pub. Date: Oct. 15, 2020

(54) ORGANIC SEMICONDUCTOR TRANSISTORS

(71) Applicant: Flexenable Limited, Cambridge (GB)

(72) Inventors: Guillaume Fichet, Cambridge (GB); Rebekka Willcocks, Cambridge (GB); Elizabeth Speechley, Cambridge (GB)

(21) Appl. No.: 16/844,578

(22) Filed: Apr. 9, 2020

(30) Foreign Application Priority Data
Apr. 12, 2019 (GB) 1905208.3

(51) Int. Cl. H01L 51/10; H01L 51/00; H01L 27/28; H01L 51/05

(52) U.S. Cl. CPC H01L 51/105; H01L 51/0023; H01L 51/0097; H01L 51/0541; H01L 27/283

(57) ABSTRACT

A technique comprising: forming a conductor layer in contact with a dielectric layer; patterning the conductor layer using an acidic patterning agent to form a source-drain conductor pattern for one or more transistors at a surface of a workpiece; and forming an organic semiconductor layer over the surface of the workpiece to provide one or more semiconductor channels for the one or more transistors; wherein the method further comprises: prior to forming the conductor layer, treating the dielectric layer with an alkaline agent.

### CLAIM OF PRIORITY

This application claims priority to Great Britain Patent Application No. 1905208.3, filed Apr. 12, 2019, the content of which is hereby incorporated by reference in its entirety.

### FIELD OF THE INVENTION

The production of transistors on plastics support films using organic semiconductor material for the semiconductor channels is of increasing interest for e.g. the mass production of electronic devices such as displays and sensor devices.

The inventors for the present application have conducted research around improving the production of such transistors on plastics support films and have made some surprising findings.

The present invention provides a method comprising: forming a conductor layer in contact with a dielectric layer; patterning the conductor layer using an acidic patterning agent to form a source-drain conductor pattern for one or more transistors at a surface of a workpiece; and forming an organic semiconductor layer over the surface of the workpiece to provide one or more semiconductor channels for the one or more transistors; wherein the method further comprises: prior to forming the conductor layer, treating the dielectric layer with an alkaline agent.

According to one embodiment, treating the dielectric layer with an alkaline agent forms part of a process of patterning the dielectric layer.

According to one embodiment, the conductor layer is the bottom layer of stack of conductor layers, and the patterning comprises patterning the stack of conductor layers.

According to one embodiment, the dielectric layer comprises a non-cross-linked organic polymer material.

According to one embodiment, the alkaline agent comprises an organic base.

According to one embodiment, the alkaline agent comprises a strong base.

According to one embodiment, the method further comprises forming the dielectric layer in situ on a hard coat of a support film component.

There is also provided apparatus, comprising: a stack of layers defining one or more transistor devices, wherein the stack of layers includes: an organic semiconductor layer providing semiconductor channels for the one or more transistor devices; a conductor layer providing the source and drain conductors for the one or more transistor devices; and non-crosslinked organic polymer dielectric layers on both sides of the organic semiconductor layer, wherein one of the non-crosslinked organic polymer dielectric layers is in contact with the source and drain conductors on one side of the organic semiconductor layer; and one of the non-crosslinked organic polymer dielectric layers is in contact with the organic semiconductor layer in at least the regions of the semiconductor channels on an opposite side of the organic semiconductor layer.

According to one embodiment, the non-crosslinked organic polymer dielectric layers have the same composition.

According to one embodiment, the one or more transistor devices comprise one or more top-gate transistor devices.

According to one embodiment, the apparatus further comprises a plastics support film, and a hard coat between the plastics support film and the non-crosslinked organic polymer dielectric layer under the organic semiconductor layer.

There is also provided a method comprising: forming a stack of layers defining one or more transistor devices, wherein the stack of layers comprises an organic polymer semiconductor providing semiconductor channels for the one or more transistor devices; wherein forming the stack of layers comprises: forming a first non-crosslinked organic polymer dielectric layer on a substrate; without subjecting the first non-crosslinked polymer dielectric layer to any crosslinking treatment, forming a source-drain conductor pattern in contact with an upper surface of the first non-crosslinked polymer dielectric layer; forming the organic polymer semiconductor layer over the upper surface of the non-crosslinked organic polymer dielectric layer at least in the regions of the semiconductor channels; and forming a second non-crosslinked organic polymer dielectric layer in contact with the upper surface of the organic semiconductor layer at least in the regions of the semiconductor channels.

According to one embodiment, the first and second non-crosslinked organic polymer dielectric layers have the same composition.

According to one embodiment, the method further comprises forming the first non-crosslinked polymer dielectric layer in situ on a hard coat of a support film component.

### BRIEF DESCRIPTION OF THE FIGURES

Embodiments of the present invention are described in detail hereunder, by way of example only, with reference to the accompanying drawings, in which:

FIGS. 1-14 illustrate an example of a technique for producing one or more transistors on a plastics support film component;

FIGS. 15 and 16 show a comparison of the transfer curves for a device produced by a technique according to an embodiment of the present invention against a device produced by a reference technique.

### DETAILED DESCRIPTION

In one example embodiment, the organic transistor device may be an organic thin film transistor (OTFT) device forming a control component for e.g. an organic liquid crystal display (OLCD) device. OTFTs comprise an organic semiconductor (such as e.g. an organic polymer or small-molecule semiconductor) for the semiconductor channels.

The detailed description below makes mention of specific process details (specific materials etc.) that are not essential to achieving the technical effects described below. The mention of such specific process details is by way of example only, and other specific materials, processing conditions etc. may alternatively be used within the general teaching of the present application.

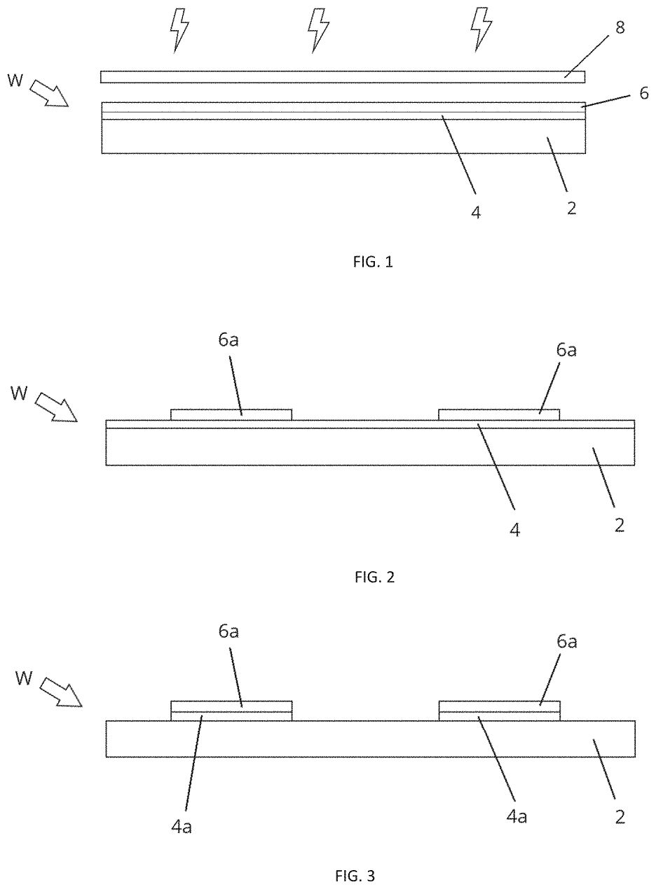

With reference to FIG. 1, processing of a workpiece W starts with the formation of a layer of a non-crosslinked organic polymer dielectric material 4 in situ on a hard coat surface (e.g. surface of a layer of a cross-linked polymer such as the epoxy-based polymer known as SU-8) of a plastics film support component 2. The plastics support film component 2 comprises at least one plastics support film and the top hard coat mentioned, and may additionally comprise one or more layers between the plastics support film and the hard coat such as a patterned conductor layer that shields the organic semiconductor channels of the transistors against the incidence of light via the transparent plastics support film. In this example, the non-crosslinked organic polymer material comprises Lisicon®-D320 available from Merck Performance Materials GmbH, which has a relatively low dielectric constant (k), and the layer of the non-crosslinked polymer dielectric material 4 is formed by a liquid processing technique such as spin-coating etc. followed by baking at about 90° C. A layer of photoresist material 6 is then formed in situ on the new upper surface of the workpiece W. In this example, the photoresist material is a positive resist material AZ® TFP 650 F5 available from Microchemicals GmbH, and the layer of photoresist material 6 is formed by a liquid processing technique such as spin-coating, followed by baking to decrease the solubility of the photoresist material (solubility in the developer agent mentioned later) over the whole area of the photoresist layer 6. The photoresist layer 6 is then exposed to a negative radiation image of the pattern desired for the non-crosslinked polymer dielectric layer 4 at a radiation frequency that induces an increase in the solubility of the photoresist material (solubility in the developer agent mentioned below) either immediately or after a further treatment such as baking. The exposure of the photoresist layer 6 to the negative radiation image is achieved using a photomask 8 that is used again later in the production technique to pattern an organic semiconductor layer 14.

With reference to FIG. 2, the latent solubility image in the photoresist layer 6 is then developed by exposing the upper surface of the workpiece W to an alkaline developer agent, to create a patterned photoresist mask 6a at the upper surface of the workpiece W. In this example, the alkaline developer agent is an aqueous solution of tetramethylammonium hydroxide (TMAH). TMAH is a strong organic base which dissociates completely in aqueous solution.

With reference to FIG. 3, the upper surface of the workpiece W is exposed to a reactive ion etching (RIE) plasma that etches the non-crosslinked polymer dielectric material 4. The patterned photoresist mask 6a functions to enable patterning of the non-crosslinked polymer dielectric layer 4. The plastics support film component 2 is exposed in the regions uncovered by the photoresist mask 6a, without substantially any reduction of the thickness of the non-crosslinked polymer dielectric layer 4 in regions covered by the photoresist mask 6a. In this example, the patterning of the non-crosslinked polymer dielectric layer 4 produces a pattern comprising an array of islands each island in the region of the semiconductor channel of a respective transistor. The patterning also exposes the hard coat surface in peripheral regions outside the array of transistors, including regions in which addressing/routing conductors of the source-drain conductor pattern will be in closest proximity to each other, such as a region in which the addressing/routing conductors are to be electrically connected by fine pitch bonding to respective conductors of a separate component (e.g. chip-on-flex (COF) component) including one or more driver chips. The adhesion between the hard coat and the source-drain conductor pattern is better than the adhesion between the non-crosslinked polymer dielectric layer 4 and the source-drain conductor pattern.

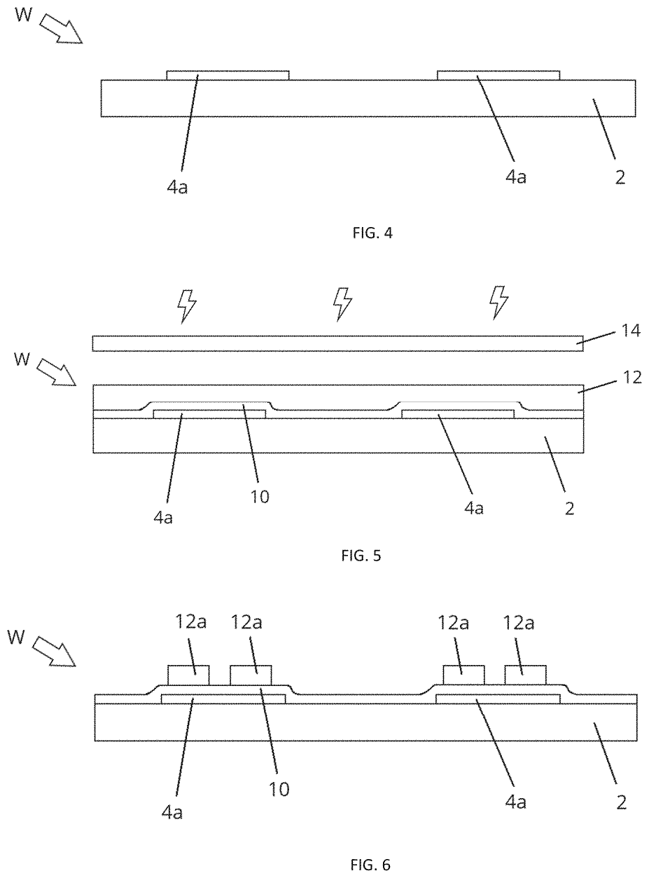

With reference to FIG. 4, the upper surface of the workpiece W is thereafter exposed to radiation at a radiation frequency that induces a decrease in the solubility of the photoresist material 6a (either immediately or after a further treatment such as baking), followed by treatment of the upper surface of the workpiece W with the alkaline developer agent mentioned above, to remove the remaining photoresist material 6a, and leave the patterned non-crosslinked polymer dielectric layer 4a at the upper surface of the workpiece W.

With reference to FIG. 5, a stack 10 of conductor layers is thereafter formed in situ on the upper surface of the workpiece W. In this example, the stack 10 of conductor layers comprises a layer of a molybdenum-tantalum (MoTa) alloy in contact with the plastics support film component 2 and the patterned non-crosslinked polymer dielectric layer 4a; and a layer of a more chemically inert metal such as e.g. gold over the MoTa layer. The MoTa layer functions to improve the adhesion of the more chemically inert, gold layer to the plastics support film component 2 and the patterned non-crosslinked dielectric layer 4a. Another layer of photoresist 12 is thereafter formed in situ from solution over the new upper surface of the workpiece W by a liquid processing technique such as e.g. spin-coating, and subjected to baking to decrease the solubility of the photoresist material (solubility in the developer agent mentioned below) over the whole area of the photoresist layer 12. The photoresist layer 12 is thereafter exposed to a negative radiation image of the desired source-drain conductor pattern for the transistors (using a photomask 14), at a radiation frequency that induces an increase in the solubility of the photoresist material in the developer agent mentioned below, either immediately or after a post-treatment such as baking.

With reference to FIG. 6, the latent solubility image in the photoresist layer 12 is developed using an alkaline developer agent to create a pattern in the photoresist layer 12 that corresponds to the desired source-drain conductor pattern.

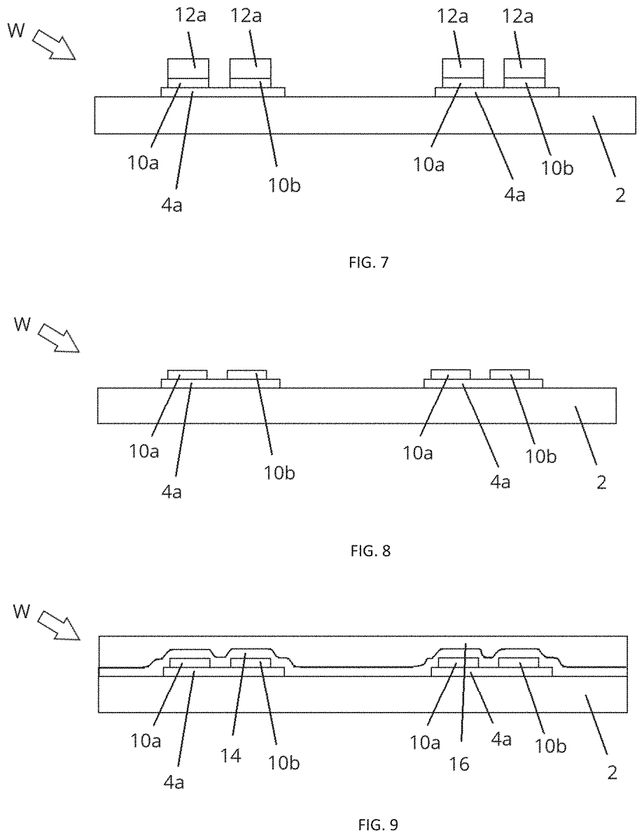

With reference to FIG. 7, the upper surface of the workpiece W is thereafter exposed to one or more etching agents for etching the stack of conductor layers. The patterned photoresist mask 12a functions to enable patterning of the stack of conductor layers 10. The plastics support film component 2 and non-crosslinked polymer dielectric layer 4a are exposed in the regions uncovered by the photoresist mask 12a, without substantially any reduction of the thickness of the stack of conductor layers 10 in regions covered by the photoresist mask 12a. The etchant used for etching at least the conductor layer in contact with the non-crosslinked polymer dielectric 4a (e.g. MoTa layer) is an acidic etchant such as e.g. an aqueous solution of phosphoric acid.

For simplicity, FIG. 7 shows only parts of the source-drain conductor pattern 10a that form source-drain electrodes defining the channel length of the semiconductor channels of the transistors, but the source-drain conductor pattern 10a may comprise additional parts such as addressing/routing lines that extend from the electrode parts over the edges of the non-crosslinked polymer dielectric pattern 4a to a peripheral part of the workpiece outside the array of transistor. For the example of the transistors forming an active matrix addressing circuit for e.g. a LCD device, the source-drain conductor pattern 10a may comprise (i) an array of source conductors each providing the source electrodes for a respective row of transistors, and each extending to a region outside the active display area; and (ii) an array of drain conductors each providing the drain conductor for a respective transistor.

With reference to FIG. 8, the remaining photoresist material is thereafter removed by exposing the upper surface of the workpiece W to radiation at a radiation frequency that increases the solubility of the remaining photoresist material (solubility in the developer agent mentioned above), either immediately or after a post-treatment such as baking; and thereafter exposing the upper surface of the workpiece W to the alkaline developer agent.

Organic charge-injection material (not shown) that bonds (e.g. gold-thiol bonds or silver-thiol bonds in the case of a source-drain conductor pattern having an upper gold or silver surface) selectively to the source-drain conductor pattern (without substantially any bonding to the workpiece in the regions in which the source/drain conductor stack has been removed by the above-described patterning) is thereafter deposited from solution over the upper surface of the workpiece W by e.g. spin-coating to form a self-assembled monolayer (SAM) of the organic injection material selectively on the exposed surface of the source/drain conductor pattern 10a. This SAM further facilitates the transfer of charge carriers between the source-drain conductors and the organic semiconductor material 14 mentioned below.

With reference to FIG. 9, a layer of organic polymer semiconductor material 14 is thereafter formed in situ on the upper surface of the workpiece W (for physical contact with the non-crosslinked polymer dielectric material 4a in e.g. the channel regions, and for physical contact with the charge-injection SAM on the source-drain conductor pattern 10) by a liquid processing technique such as e.g. spin-coating, and a layer of non-crosslinked polymer dielectric material 16 is formed on the upper surface of the organic semiconductor layer 14 by a liquid processing technique such as e.g. spin-coating. In this example, the non-crosslinked polymer dielectric layers 4, 16 above and below the organic polymer semiconductor 14 comprise the same polymer material having a relatively low dielectric constant (k).

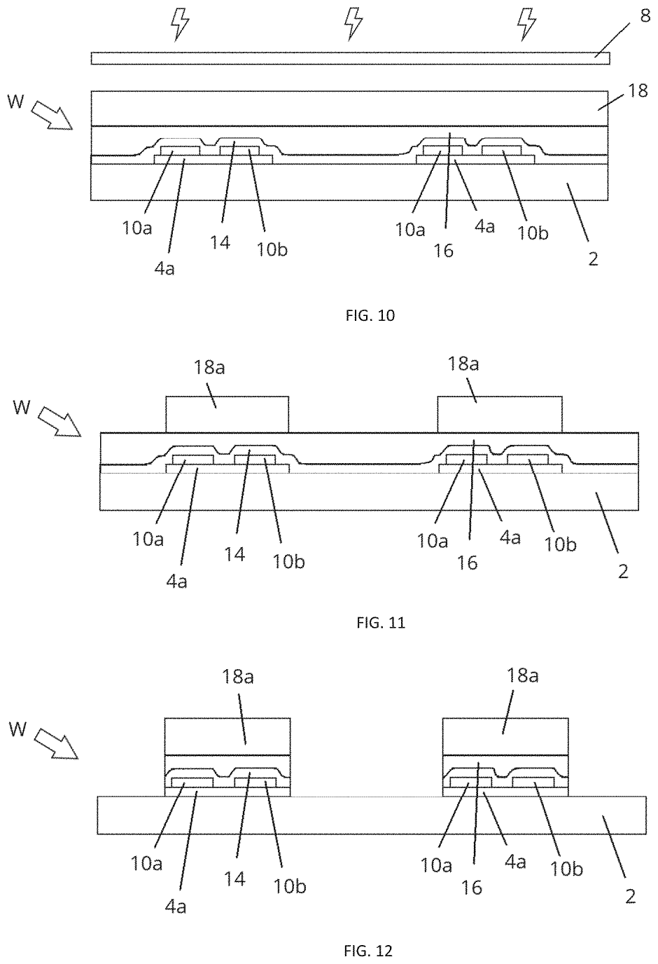

With reference to FIG. 10, a layer of positive photoresist material 18 is thereafter formed in situ over the new upper surface of the workpiece W by a liquid processing technique such as e.g. spin-coating, followed by baking to decrease the solubility of the photoresist material in the developer agent mentioned below. The upper surface of the workpiece W is thereafter exposed to a negative radiation image of the pattern desired for the organic semiconductor and upper low-k dielectric layers 14, 16 at a radiation frequency that induces an increase in the solubility of the photoresist material (solubility in the developer agent mentioned below), either immediately or after a post-treatment such as baking.

With reference to FIG. 11, the latent solubility image in the photoresist layer 18 is developed by exposing the new upper surface of the workpiece W to a developer agent, to create a pattern in the photoresist layer 18 that corresponds to the desired pattern for the organic semiconductor and low-k dielectric layers 14, 16.

With reference to FIG. 12, the upper surface of the workpiece W is thereafter exposed to a reactive ion etching (RIE) plasma that etches the organic semiconductor and low-k dielectric layers 14, 16. The patterned photoresist mask 18a functions to enable patterning of the organic semiconductor and low-k dielectric layers 14, 16; the entire thickness of the organic semiconductor and low-k dielectric layers 14, 16 is removed in the regions uncovered by the photoresist mask 18a, without substantially any reduction of the thickness of the organic semiconductor and low-k dielectric layers 14, 16 in regions covered by the photoresist mask 18a.

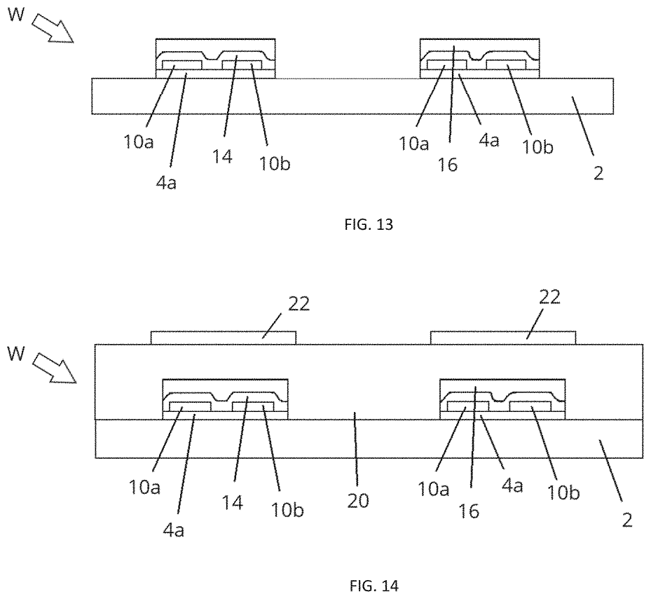

With reference to FIG. 13, the upper surface of the workpiece W is thereafter exposed to radiation at a radiation frequency that induces a decrease in the solubility of the remaining photoresist material 18a (solubility in the developer agent) either immediately or after a post-treatment such as baking, followed by treatment of the upper surface of the workpiece W with the developer agent mentioned above to remove the remaining photoresist material.

In this example, the photomask 8 used for patterning this photoresist layer 18 is the same as the photomask 8 used for patterning the photoresist layer 6 used for patterning the non-crosslinked polymer dielectric layer 4; and the alignment of the photomasks 8 with respect to the plastics support film component 2 in these two stages is the same, such that the pattern created in the organic semiconductor and low-k dielectric layers 14, 16 is both (i) substantially the same as the pattern in the non-crosslinked dielectric layer 4 and (ii) substantially aligned to the pattern in the non-crosslinked polymer dielectric layer 4.

With reference to FIG. 14, a further layer of organic polymer dielectric material 20 is thereafter formed in situ on the new upper surface of the workpiece W by a liquid processing technique such as e.g. spin coating. The further layer of organic polymer dielectric material 20 has a higher dielectric constant (k) than the layer of organic polymer dielectric material 16 in physical contact with the organic semiconductor 14. A gate conductor pattern 22 is thereafter formed in situ on the upper surface of the further layer of organic polymer dielectric material 20. In this example, a metal layer (or a stack of metal layers) is formed in situ on the upper surface of the upper dielectric material 20 by a vapour deposition technique such as sputtering, and is patterned by a photolithographic technique. For the example of the transistors forming an active matrix addressing circuit for e.g. a LCD device, the gate conductor pattern 22 may comprise an array of gate conductors each providing the gate electrode for a respective column of transistors, and each extending to a region outside the active display area. Each transistor in the active matrix array is associated with a respective unique combination of gate and source conductors, whereby each transistor can be independently addressed via parts of the gate and source conductors outside the active display area.

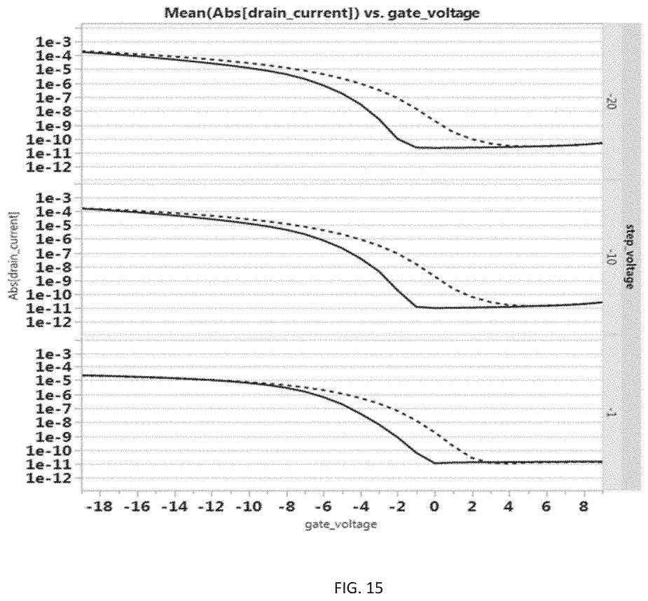

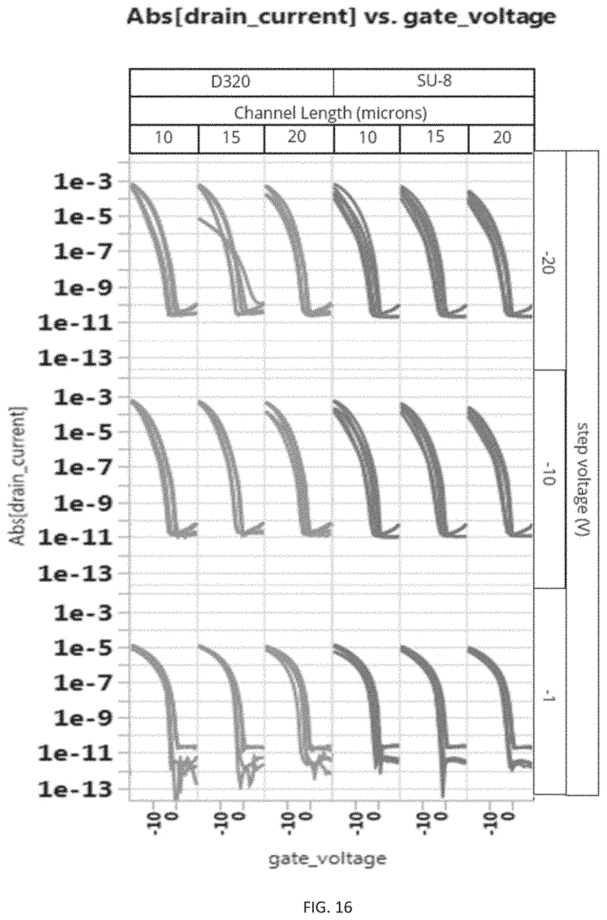

In the process of investigating the effect of introducing a patterned non-crosslinked organic polymer dielectric layer 4 under the source-drain conductor pattern in a top-gate transistor device, the inventors for the present application made the following surprising findings. Not only did the use of a non-crosslinked polymer dielectric layer under the source-drain conductor pattern not produce a deterioration (compared to the use of a cross-linked polymer dielectric layer below the source-drain conductor pattern) in the transfer curve for the transistor(s), but there was observed an improvement in the transfer curve. Furthermore, it was observed that this improvement was linked to the process of patterning the non-crosslinked polymer dielectric layer. FIG. 15 shows the results of comparative measurements of the transfer curve for (i) a transistor device produced as described in detail above (solid line in FIG. 15), and (ii) a transistor device that was produced by the same process except for omitting patterning of the non-crosslinked polymer dielectric layer 4 (dashed line in FIG. 15). FIG. 16 shows the results of comparative measurements of the transfer curve for (ii) a transistor device produced as described above but without patterning of the non-crosslinked dielectric layer (column labelled D320 in FIG. 16), and (iii) a transistor device produced as described above but wherein the source-drain conductor pattern is instead formed on the upper surface of an unpatterned crosslinked epoxy-based polymer dielectric layer (column labelled SU-8 in FIG. 16). Without wishing to be bound by theory, the inventors for the present application attribute the improvement in the transfer curve to alkaline species (from the alkaline developer agent used to remove the photoresist pattern 6a) remaining in the patterned non-crosslinked polymer layer 4. It is believed that some interaction between these residual alkaline species and the acidic species from the acidic etchant used to pattern the source-drain conductor pattern is behind the improvement in the transfer curve. In more detail, it is believed that a residue of alkaline species in the non-crosslinked polymer dielectric layer 4 functions to better prevent the generation of a residue of acidic species (from the acidic etchant used in the patterning of the source-drain conductor pattern) in the non-crosslinked polymer dielectric layer 4, and that this reduction or elimination of acidic species in the non-crosslinked polymer dielectric layer 4 is behind the improvement in the transfer curve of the transistor.

As mentioned above, the alkaline agent is an aqueous solution of a strong organic base, TMAH. Other alkaline agents can be used including both inorganic and organic strong bases, which dissociate completely in aqueous solution.

As mentioned above, an example of a technique according to the present invention has been described in detail above with reference to specific process details, but the technique is more widely applicable within the general teaching of the present application. Additionally, and in accordance with the general teaching of the present invention, a technique according to the present invention may include additional process steps not described above, and/or omit some of the process steps described above.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method comprising: forming a conductor layer in contact with a dielectric layer; patterning the conductor layer using an acidic patterning agent to form a source-drain conductor pattern for one or more transistors at a surface of a workpiece; and forming an organic semiconductor layer over the surface of the workpiece to provide one or more semiconductor channels for the one or more transistors; wherein the method further comprises: prior to forming the conductor layer, treating the dielectric layer with an alkaline agent.

2. The method according to claim 1, wherein treating the dielectric layer with an alkaline agent forms part of a process of patterning the dielectric layer.

3. The method according to claim 1, wherein the conductor layer is the bottom layer of stack of conductor layers, and the patterning comprises patterning the stack of conductor layers.

4. The method according to claim 1, wherein the dielectric layer comprises a non-cross-linked organic polymer material.

5. The method according to claim 1, wherein the alkaline agent comprises an organic base.

6. The method according to claim 1, wherein the alkaline agent comprises a strong base.

7. The method according to claim 1, further comprising forming the dielectric layer in situ on a hard coat of a support film component.

8. An apparatus, comprising: a stack of layers defining one or more transistor devices, wherein the stack of layers includes: an organic semiconductor layer providing semiconductor channels for the one or more transistor devices; a conductor layer providing the source and drain conductors for the one or more transistor devices; and non-crosslinked organic polymer dielectric layers on both sides of the organic semiconductor layer, wherein one of the non-crosslinked organic polymer dielectric layers is in contact with the source and drain conductors on one side of the organic semiconductor layer; and one of the non-crosslinked organic polymer dielectric layers is in contact with the organic semiconductor layer in at least the regions of the semiconductor channels on an opposite side of the organic semiconductor layer.

9. The apparatus according to claim 8, wherein the non-crosslinked organic polymer dielectric layers have the same composition.

10. The apparatus according to claim 8, wherein the one or more transistor devices comprise one or more top-gate transistor devices.

12. The apparatus according to claim 8, further comprising a plastics support film, and a hard coat between the plastics support film and the non-crosslinked organic polymer dielectric layer under the organic semiconductor layer.

13. The apparatus according to claim 9, further comprising a plastics support film, and a hard coat between the plastics support film and the non-crosslinked organic polymer dielectric layer under the organic semiconductor layer.

14. The apparatus according to claim 10, further comprising a plastics support film, and a hard coat between the plastics support film and the non-crosslinked organic polymer dielectric layer under the organic semiconductor layer.

15. A method comprising: forming a stack of layers defining one or more transistor devices, wherein the stack of layers comprises an organic polymer semiconductor providing semiconductor channels for the one or more transistor devices; wherein forming the stack of layers comprises: forming a first non-crosslinked organic polymer dielectric layer on a substrate; without subjecting the first non-crosslinked polymer dielectric layer to any crosslinking treatment, forming a source-drain conductor pattern in contact with an upper surface of the first non-crosslinked polymer dielectric layer; forming the organic polymer semiconductor layer over the upper surface of the non-crosslinked organic polymer dielectric layer at least in the regions of the semiconductor channels; and forming a second non-crosslinked organic polymer dielectric layer in contact with the upper surface of the organic semiconductor layer at least in the regions of the semiconductor channels.

16. The method according to claim 15, wherein the first and second non-crosslinked organic polymer dielectric layers have the same composition.

17. The method according to claim 15, further comprising forming the first non-crosslinked polymer dielectric layer in situ on a hard coat of a support film component.
